(19) United States
(12) Patent Application Publication
(10) Pub. No.: US 2026/0107612 A1
(43) Pub. Date: Apr. 16, 2026

(54) DISPLAY DEVICE INCLUDING A PAD AND METHOD OF MANUFACTURING THE SAME

(71) Applicant: SAMSUNG DISPLAY CO., LTD., YONGIN-SI (KR)

(72) Inventors: HEEJU WOO, Yongin-si (KR); KIYONG KIM, Yongin-si (KR); CHOLONG WON, Yongin-si (KR); HYUNGBIN CHO, Yongin-si (KR)

(21) Appl. No.: 19/258,464

(22) Filed: Jul. 2, 2025

(30) Foreign Application Priority Data
Oct. 16, 2024 (KR) 10-2024-0141318

(51) Int. Cl. H10H 29/49; H01L 25/16; H10H 29/01

(52) U.S. Cl. CPC H10H 29/49; H10H 29/012; H10H 29/0364; H10W 90/00

(57) ABSTRACT

A display device includes a substrate including a display area and a non-display area. A pad portion is disposed in the non-display area and includes a pad area in which a pad is disposed and a non-pad area surrounding the pad area. First and second pattern layers partially overlap the pad and are spaced apart from each other. The first pattern layer may overlap a portion of the pad area and a portion of the non-pad area, and the second pattern layer may overlap a portion of the pad area and may include a center line of the pad. In a maximum height measured in a first direction that is perpendicular to an upper surface of the substrate from the upper surface thereof, a first height of the first pattern layer may be greater than a second height of the second pattern layer.

### CROSS-REFERENCE TO RELATED APPLICATION

This application claims priority under 35 U.S.C. § 119 to Korean Patent Application No. 10-2024-0141318, filed at the Korean Intellectual Property Office on Oct. 16, 2024, the entire contents of which are herein incorporated by reference.

### TECHNICAL FIELD

The present disclosure relates to a display device and a method of manufacturing the same, and more specifically, to a display device including a pad and a method of manufacturing a display device including a pad.

### DISCUSSION OF THE RELATED ART

A display device, such as a light emitting display device, typically includes a display panel that includes pixels that display images. To operate the display panel, a pad portion may be incorporated. The pad portion includes pads for inputting and outputting signals. A driver, which includes an integrated circuit (IC) to control the display, is located within this pad portion.

For establishing both electrical connections and physical bonding between the driver and the substrate, an anisotropic conductive film (ACF) may be used. This film includes conductive particles that are embedded within an insulating layer. It conducts electricity in its thickness direction while remaining insulating along its plane.

However, the use of ACF may lead to certain issues such as short circuits that may occur between adjacent pads due to conductive particles within the film. Additionally, bonding defects may arise between the pad and the bump electrode of the driver, thereby affecting performance and reliability.

### SUMMARY

A display device includes a substrate including a display area and a non-display area that is proximate to the display area. A pad portion is disposed in the non-display area and includes a pad area in which a pad is disposed and a non-pad area surrounding the pad area. A first pattern layer and a second pattern layer partially overlap the pad and spaced apart from each other.

The first pattern layer may overlap a portion of the pad area and a portion of the non-pad area. The second pattern layer may overlap a portion of the pad area and may include a center line of the pad, and in a maximum height measured in a first direction that is perpendicular to an upper surface of the substrate from the upper surface thereof, a first height of the first pattern layer may be higher than a second height of the second pattern layer.

The first pattern layer may include a single first segment.

The first pattern layer may include a plurality of first segments that are spaced apart from each other.

The second pattern layer may include a single second segment.

The second pattern layer may include a plurality of second segments that are spaced apart from each other.

A maximum thickness of the second pattern layer, measured in the first direction, may be within a range of 0.5 μm to 3 μm, inclusive.

The first pattern layer may be disposed on one side of the second pattern layer.

The display device may further include a driver that drives the display device, and the driver may include a driving integrated circuit and a driving bump connecting the driving integrated circuit to the substrate.

The display device may further include a conductive layer formed on the first pattern layer and the second pattern layer, and the driving bump may be in contact with the conductive layer.

The driving bump may be in contact with the conductive layer disposed on the first pattern layer and the conductive layer disposed on the second pattern layer.

The driving bump may be in contact with the conductive layer disposed on a side surface of the first pattern layer.

The side surface of the first pattern layer may have an inclined surface, and the driving bump may be in contact with the conductive layer disposed on the inclined surface.

An area in which the driving bump of the driver and the conductive layer disposed on the side surface of the first pattern layer are in contact with each other may have an inclined surface.

The driving bump may be in contact with the conductive layer disposed on an upper surface of the second pattern layer.

An electronic device includes a display device having a substrate including a display area and a non-display area that is proximate to the display area. A pad portion is disposed in the non-display area and includes a pad area in which a pad is disposed and a non-pad area surrounding the pad area. A first pattern layer and a second pattern layer partially overlap the pad and are spaced apart from each other. The first pattern layer overlaps a portion of the pad area and a portion of the non-pad area. The second pattern layer overlaps a portion of the pad area and includes a center line of the pad. In a maximum height measured in a first direction that is perpendicular to an upper surface of the substrate from the upper surface thereof, a first height of the first pattern layer is greater than a second height of the second pattern layer.

A method of manufacturing a display device, includes forming, in a pad portion, a plurality of pattern layers partially overlapping a pad, the pad portion disposed in a non-display area of the display panel and including a pad area in which the pad is disposed and a non-pad area surrounding the pad area. A conductive layer is formed on the plurality of pattern layers. A driver including a driving bump and a driving integrated circuit overlap the pad on the plurality of pattern layers. The driving bump is bonded to the conductive layer to attach the driver to the pad.

The forming of the pattern layers includes preparing a photomask including a first mask pattern and a second mask pattern having lower light transmittance than the first mask pattern. The forming of the pattern layers includes forming a first pattern layer corresponding to the first mask pattern and a second pattern layer corresponding to the second mask pattern using the photomask.

The forming of the pattern layers may include forming the first pattern layer overlapping a portion of the pad area and a portion of the non-pad area, and forming the second pattern layer overlapping a portion of the pad area and include a center line of the pad.

The forming of the pattern layers may include forming the first pattern layer using the first mask pattern having a light transmittance of 95% or more.

The forming of the pattern layers may include forming the second pattern layer using the second mask pattern having a light transmittance within a range of 40% to 60%, inclusive.

The forming of the pattern layers may include forming a maximum thickness of the first pattern layer to be greater than that of the second pattern layer, thickness measured in a first direction that is perpendicular to a lower surface of the pattern layers.

The forming of the pattern layers may include exposing the pattern layers to light so that the first pattern layer has a maximum thickness within a range of 2 μm to 5 μm, inclusive, and the second pattern layer has a maximum thickness within a range of 0.5 μm to 3 μm, inclusive.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 and FIG. 2 are a schematic exploded perspective view and a top plan view of a display device according to an embodiment, respectively.

FIG. 3 is a cross-sectional view of components disposed in a display area of a display device according to an embodiment.

FIG. 4 is a schematic top plan view of a portion of a pad portion of a display device according to an embodiment.

FIG. 5 is a schematic top plan view of an area including one pad of a pad portion of a display device according to an embodiment.

FIG. 6 is a schematic cross-sectional view of an area including one pad of a pad portion of a display device according to an embodiment.

FIG. 7, FIG. 8, FIG. 9, and FIG. 10 are schematic top plan views of an area including one pad of a pad portion of a display device according to an embodiment.

FIG. 11 and FIG. 12 are schematic diagrams of a method of manufacturing a display device according to an embodiment.

FIG. 13 is a block diagram of an electronic device according to an embodiment.

FIG. 14 includes schematic diagrams of electronic devices according to various embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To the extent that an element is not described in detail with respect to this figure, it may be understood that the element is at least similar to a corresponding element that has been described elsewhere within the present disclosure.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Also, when an element such as a layer, film, region, plate, etc. is referred to as being “on” another element, this includes not only when it is “directly on” the other element, but also when there is another part in between. In contrast, when an element is referred to as being “directly on” another element, there are no intervening elements present. Further, being “on” or “above” an element means being disposed above or below the element and does not necessarily mean being “on”or “above”the element based on a gravitational direction.

In addition, unless explicitly stated to the contrary, the word “comprise,” and variations such as “comprises” and “comprising,” should be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Embodiments of the present disclosure relate to a display device and a manufacturing method aimed at improving connection stability and reliability between the driver and the substrate. This is achieved by introducing a pad portion with a specifically designed pattern layer system, including a first and second pattern layer, each with different heights and configurations, to enhance the contact area, bonding strength, and reduce resistance between the driving bump and the pad.

According to this approach, the first and second pattern layers may overlap parts of the pad and are spaced to optimize electrical connections and stability. The layers ensure better contact with the conductive layer, reducing defects like shorts and enhancing attachment reliability.

The manufacturing process used for producing such a display device utilizes photomasks with varying light transmittance to achieve precise layer configurations.

This innovation is intended for application in a range of electronic devices, including smartphones, tablet computers, wearable devices, and automotive displays, to ensure higher durability and performance in display technology.

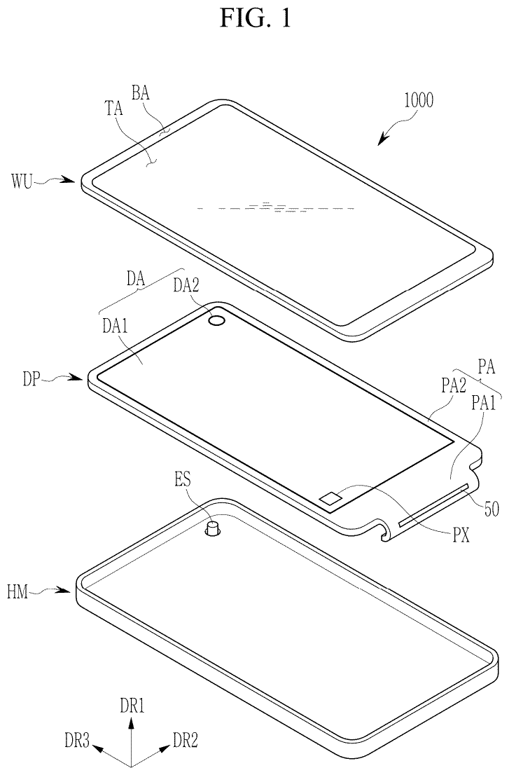

FIG. 1 is a schematic exploded perspective view of a display device according to an embodiment.

Referring to FIG. 1, a display device 1000 is a device for displaying a moving image or a still image, and may be used as a display screen of a portable electronic device such as a mobile phone, a smartphone, a tablet computer, a mobile communication terminal, an electronic notebook, an electronic book, a portable multimedia player (PMP), a navigation device, and an ultramobile PC (UMPC), and may be used as a display screen of various products such as a television set, a laptop computer, a computer monitor, a digital billboard, and an Internet of things (IOT) device. In addition, the display device 1000 may be used in a wearable device such as a smartwatch, a watch phone, an eyewear display and a head-mounted display (HMD). The display device 1000 may be used as a center information display (CID) disposed on an instrument panel, a center fascia, or a dashboard of a vehicle, a room mirror display that replaces a side mirror of a vehicle, and display disposed on the back of a front seat for entertainment for a rear seat of a vehicle. For better comprehension and ease of description, FIG. 1 illustrates a case in which that the display device 1000 is used for a smartphone.

The display device 1000 may display an image toward a first direction DR1 on a display surface that extends in each of a second direction DR2 and a third direction DR3. A display surface on which an image is displayed may correspond to a front surface of the display device 1000, and may correspond to a front surface of a cover window WU. An image may include a static image as well as a dynamic image.

In the present disclosure, a front (or top) surface and a rear (or bottom) surface of each member are defined based on a direction in which an image is displayed. The front and rear surfaces may be opposite to each other in the first direction DR1, and a normal direction of each of the front and rear surfaces may be in the first direction DR1. A separation distance in the first direction DR1 between the front and rear surfaces may correspond to a thickness of a display panel in the first direction DR1.

The display device 1000 may detect a user input applied thereto. The user's input may include various types of external inputs such as a part of the user's body, light, heat, or pressure. The user's input may be variously provided, and the display device 1000 may sense the user's input applied to the lateral or rear surface of the display device 1000 according to the structure of the display device 1000.

The display device 1000 may include the cover window WU, a housing HM, a display panel DP, and an optical element ES. In one embodiment, the cover window WU and the housing HM may be combined to form an appearance of the display device 1000.

The cover window WU may include an insulating panel. For example, the cover window WU may be made of glass, plastic or a combination thereof.

A front surface of the cover window WU may define the front surface of the display device 1000. A transmission area TA may be an optically transparent area. For example, the transmission area TA may be an area having visible ray transmittance of about 90% or more.

A blocking area BA may define a shape of the transmission area TA. The blocking area BA may be adjacent to the transmission area TA, and may surround the transmission area TA. The blocking area BA may be an area having relatively low light transmittance compared with the transmission area TA. The blocking area BA may include an opaque material that blocks light.

The display panel DP may include a front surface that includes a display area DA and a non-display area PA. The display area DA may be an area in which a pixel operates to emit light according to an electrical signal.

In one embodiment, the display area DA may be an area that includes a pixel and in which an image is displayed, and may be an area in which a touch sensor is disposed at an upper side of the pixel in the first direction DR1 to sense an external input.

The transmission area TA of the cover window WU may at least partially overlap the display area DA of the display panel DP. For example, the transmission area TA may overlap the front surface of the display area DA, or may overlap at least a portion of the display area DA. Accordingly, the user may view an image through the transmission area TA, or may provide an external input based on the image. However, the present disclosure is not necessarily limited thereto. For example, the display area DA may be divided into an area in which an image is displayed and an area in which an external input is sensed.

The non-display area PA of the display panel DP may at least partially overlap the blocking area BA of the cover window WU. The non-display area PA may be an area covered by the blocking area BA. The non-display area PA may be adjacent to the display area DA, and may surround the display area DA. No image is displayed in the non-display area PA, and a driving circuit or driving wire for driving the display area DA may be disposed therein. The non-display area PA may include a first non-display area PA1 including a connecting wire and a bending area, and a second non-display area PA2 that is proximate to the display area DA.

In the embodiment, the display panel DP may be assembled in a flat state in which the display area DA and the non-display area PA are connected to the cover window WU, which may be substantially flat. However, the present disclosure is not necessarily limited thereto. A portion of the non-display area PA of the display panel DP may be bent and/or curved.

In addition, the display area DA may include a first display area DA1 and a second display area DA2. A plurality of light emitting diodes, and a plurality of pixel circuits that generate and transmit light emitting current to each of the plurality of light emitting diodes are formed in the first display area DA1. Here, one light emitting diode and one pixel circuit portion are referred to as a pixel PX.

A driving integrated circuit 50 may be mounted on the first non-display area PA1, and may be mounted on a bending portion or disposed on either side of the bending portion. The driving integrated circuit 50 may be electrically connected to the display area DA to transmit an electrical signal to the display area DA. For example, the driving integrated circuit 50 may be connected to the pixels PX disposed in the display area DA and provide data signals to them. The driving integrated circuit 50 may include various circuits in addition to the above-described circuits, or may be designed to provide various electrical signals to the display area DA.

Another pad portion may be disposed at an end of the first non-display area PA1, and the display device 1000 may be electrically connected to a flexible printed circuit board (FPCB) by the pad portion. The driving chip disposed on the flexible printed circuit board may include various driving circuits for driving the display device 1000 or connectors for supplying power. In some embodiments, instead of the flexible printed circuit board, a rigid printed circuit board (PCB) may be used.

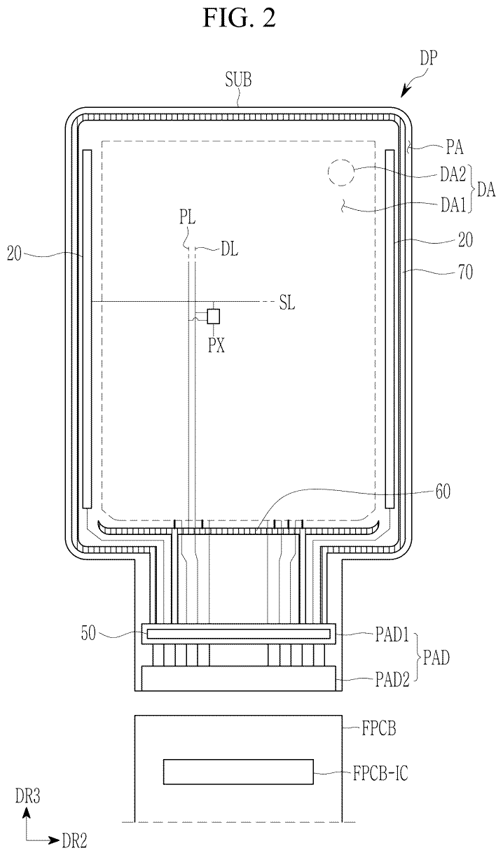

FIG. 2 is a schematic top plan view of a display panel according to an embodiment.

Referring to FIG. 2, the display panel DP may include a plurality of pixels PX. The plurality of pixels PX may be disposed within the display area DA. Each of the pixels PX may include a light emitting diode (or light emitting element) and a pixel circuit connected thereto. Each of the pixels PX may emit light of, for example, red, green, blue, or white, and may include, for example, a light emitting diode.

The display panel DP may include a plurality of signal lines and a pad portion. The plurality of signal lines may include a scan line SL extending in the first direction DR1, and a data line DL and a driving voltage line PL extending in the second direction DR2.

A scan driver 20 may be disposed on the left and right sides of the display area DA and may generate and transmit a scan signal to each pixel PX through the scan line SL. The pixel PX may receive scan signals together from two scan drivers 20 disposed on the left and right sides.

A driving voltage supply wire 60 may be disposed on the non-display area PA. For example, the driving voltage supply wire 60 may provide a driving voltage (or emitter line voltage drain, ELVDD) to the pixels PX. The driving voltage supply wire 60 may extend in the second direction DR2, and may be connected to a plurality of driving voltage lines PL extending in the third direction DR3.

A common voltage supply wire 70 may be disposed on the non-display area PA. The common voltage supply wire 70 may surround a substrate SUB. The common voltage supply wire 70 may transmit a common voltage ELVSS to one electrode (for example, cathode) of a light emitting element included in the pixel PX.

A pad portion PAD may be disposed on the non-display area PA. The pad portion PAD may include a driving pad portion PAD1 connected to the driving integrated circuit 50 and an FPCB connection pad portion connected to the flexible printed circuit board FPCB.

The driving pad portion PAD1 may extend from the data line DL to be disposed in the non-display area PA. The FPCB connection pad portion PAD2 may extend from the scan driver 20, the driving voltage supply wire 60, and the power voltage supply wire 70 to be disposed in the non-display area PA.

The driving pad portion PAD1 may extend from the data line DL to be disposed in the non-display area PA. The FPCB connection pad portion PAD2 may extend from the scan driver 20, the driving voltage supply wire 60, and the power voltage supply wire 70 to be disposed in the non-display area PA.

The driving pad portion PAD1 may be exposed without being covered by an insulating layer to be electrically connected to the driving integrated circuit 50 shown in FIG. 1. The driving integrated circuit 50 may provide a driving signal and a data signal as electrical signals to the pixel PX of the display area DA. The driving integrated circuit 50 and the driving pad portion PAD1 may be bonded through a driving bump. The driving integrated circuit 50 may be mounted on the display panel DP by a chip-on-plastic (COP) method or a chip-on-glass (COG) method.

The driving integrated circuit 50 may be disposed on the non-display area PA and may overlap the driving pad portion PAD1. The driving integrated circuit 50 may generate a data voltage to be applied to each pixel PX and transmit it to each data line DL. The driving integrated circuit 50 may be disposed on one side of the display panel DP, and for example, may be disposed between the flexible printed circuit board FPCB and the display area DA.

The FPCB connection pad portion PAD2 may be exposed without being covered by an insulating layer to be electrically connected to the flexible printed circuit board FPCB. The flexible printed circuit board FPCB may transmit a signal or power of the driving chip FPCB-IC to the FPCB connection pad portion PAD2. The flexible printed circuit board FPCB and the FPCB connection pad portion PAD2 may be bonded through a solder bump or may be electrically connected through an anisotropic conductive film.

The driving chip FPCB-IC included in the flexible printed circuit board FPCB may convert a plurality of image signals transmitted from the outside into a plurality of image data signals, and transmit the converted signals to the driving integrated circuit 50 through a plurality of pads disposed on the driving pad portion PAD1. In addition, the driving chip FPCB-IC may receive a vertical synchronization signal, a horizontal synchronization signal, and a clock signal to generate a control signal for controlling the driving of the scan driver 20 and the driving integrated circuit 50. The generated control signal may be transmitted through the pad of the FPCB connection pad portion PAD2 and the pad of the driving pad portion PAD1. The driving chip FPCB-IC may transmit the driving voltage ELVDD to the driving voltage supply wire 60 through a pad disposed on the FPCB connection pad portion PAD2. In addition, the driving chip FPCB-IC may transmit the common voltage ELVSS to each of the common voltage supply lines 70 through a pad disposed on the FPCB connection pad portion PAD2.

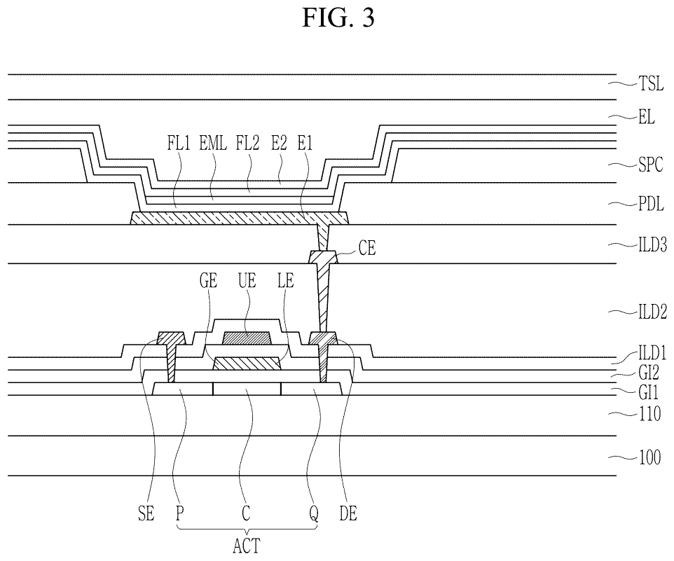

FIG. 3 is a cross-sectional view of components disposed in a display area of a display device according to an embodiment.

The display panel, according to the embodiment, may include a substrate 100. The substrate 100 may include an inorganic insulating material such as glass or an organic insulating material such as plastic such as polyimide (PI). The substrate 100 may have a single-layered structure or a multi-layered structure. The substrate 100 may have a structure in which at least one base layer and at least one inorganic layer, which include polymer resins sequentially stacked, are sequentially stacked.

The substrate 100 may be a rigid substrate. The substrate 100 may be a flexible substrate. For example, the substrate 100 may be a flexible substrate that is bendable, foldable, or rollable to at least a noticeable extent without cracking or otherwise sustaining damage.

A buffer layer 110 may be disposed on the substrate 100. The buffer layer 110 may prevent deterioration of characteristics of layers disposed on an upper portion of the buffer layer 110 from the substrate 100, for example, a semiconductor layer ACT, and relieve stress. The buffer layer 110 may include an inorganic insulating material such as a silicon nitride and a silicon oxide or an organic insulating material. A portion or all of the buffer layer 110 may be omitted. The buffer layer 110 may be formed as a portion of the substrate 100.

The semiconductor layer ACT may be disposed on the buffer layer 110. The semiconductor layer ACT may include at least one of polycrystalline silicon and an oxide semiconductor. The semiconductor layer ACT may include a channel region C, a first region P, and a second region Q. Each of the first region P and the second region Q may include a semiconductor doped with a relatively large amount of impurities compared to the channel region C. When the semiconductor layer ACT is an oxide semiconductor, a protective layer or the like may be added. Accordingly, an oxide semiconductor material vulnerable to an external environment such as high temperature may be protected.

A first gate insulating layer GI1 may be disposed on the semiconductor layer ACT. The first gate insulating layer GI1 may be a single layer or multilayer including at least one of silicon oxide (SiOₓ), silicon nitride (SiNₓ), and silicon oxynitride (SiOₓN_{y}).

A gate electrode GE and a lower electrode LE may be disposed on the first gate insulating layer GI1. The gate electrode GE and the lower electrode LE may be integrally formed. The gate electrode GE and the lower electrode LE may be a single-layer structure or a multi-layer structure in which a metal film including one of copper (Cu), a copper alloy, aluminum (Al), an aluminum alloy, molybdenum (Mo), a molybdenum alloy, titanium (Ti), and a titanium alloy is stacked. The gate electrode GE may overlap the channel region C of the semiconductor layer ACT.

A second gate insulating layer GI2 and an upper electrode UE may be disposed on the gate electrode GE, the lower electrode LE, and the first gate insulating layer GI1. The upper electrode UE and the lower electrode LE may form a capacitor.

A first insulating layer ILD1 may be disposed on the upper electrode UE. The first insulating layer ILD1 may include at least one of silicon oxide (SiOₓ), silicon nitride (SiNₓ), and silicon oxynitride (SiOₓN_{y}).

A source electrode SE and a drain electrode DE may be disposed on the first insulating layer ILD1. The source electrode SE and the drain electrode DE may be connected to the first region P and the second region Q of the semiconductor layer ACT, respectively, through a contact hole formed in the first insulating layer ILD1.

The source electrode SE and the drain electrode DE may include aluminum (Al), silver (Ag), magnesium (Mg), gold (Au), nickel (Ni), chromium (Cr), calcium (Ca), molybdenum (Mo), titanium (Ti), tungsten (W), copper (Cu), and the like. The source electrode SE and the drain electrode DE may have a single-layered or multi-layered structure including the materials.

A second insulating layer ILD2 is disposed on the first insulating layer ILD1, the source electrode SE, and the drain electrode DE. The second insulating layer ILD2 may include an organic insulating material such as a general-purpose polymer such as poly(methyl methacrylate) (PMMA) or polystyrene (PS), a polymer derivative having a phenolic group, an acryl-based polymer, an imide-based polymer, a polyimide, an acryl-based polymer, and a siloxane-based polymer. In the present disclosure, the second insulating layer ILD2 formed as a single layer is illustrated, but is not necessarily limited thereto and may be formed as a multilayer structure.

A connecting electrode CE may be disposed on the second insulating layer ILD2. The connecting electrode CE may be omitted.

A third insulating layer ILD3 and a first electrode E1 may be disposed on the second insulating layer ILD2. The first electrode E1 may be connected to the connecting electrode CE through a contact hole formed in the third insulating layer ILD3, and may be electrically connected to the drain electrode DE.

The first electrode E1 may include a metal such as silver (Ag), lithium (Li), calcium (Ca), aluminum (Al), magnesium (Mg), or gold (Au), and may also include a transparent conducting oxide (TCO) such as indium tin oxide (ITO) or indium zinc oxide (IZO). The first electrode E1 may have a single-layered structure including a metal material or a transparent conducting oxide, or a multi-layered structure including the same. For example, the first electrode E1 may have a triple-layered structure of indium tin oxide (ITO)/silver (Ag)/indium tin oxide (ITO).

A transistor configured of the gate electrode GE, the semiconductor layer ACT, the source electrode SE, and the drain electrode DE may be connected to the first electrode E1 to supply a current to a light emitting element.

A partition wall PDL may be disposed on the third insulating layer ILD3 and the first electrode E1.

The partition wall PDL may have an opening that overlaps at least a portion of the first electrode E1 and defines a light emitting area. The opening may have a planar shape substantially similar to that of the first electrode E1. The opening may have a circular shape in a plan view, but is not necessarily limited thereto, and may have various shapes such as a rhombus or an octagonal shape similar to a rhombus, a rectangular shape, a polygonal shape, and an elliptical shape.

The partition wall PDL may include an organic insulating material. Alternatively, the partition wall PDL may include an inorganic insulating material such as silicon oxide (SiOₓ), silicon nitride (SiNₓ), or silicon oxynitride (SiOₓN_{y}). The partition wall PDL may include an organic insulating material and an inorganic insulating material. For example, the partition wall PDL may include a light blocking material, and may be colored black. The light blocking material may include a resin or paste including carbon black, carbon nanotubes, and black dye, metal particles such as nickel, aluminum molybdenum, an alloy thereof, metal oxide particles such as chromium oxide, or metal nitride particles such as chromium nitride. When the partition wall PDL includes a light blocking material, reflection of external light by metal structures disposed under the partition wall PDL may be reduced.

A spacer SPC may be disposed on the partition wall PDL. The spacer SPC may include an organic insulating material such as polyimide. The spacer SPC may include an inorganic insulating material such as silicon nitride (SiNₓ) or silicon oxide (SiO₂), or may include both an organic insulating material and an inorganic insulating material.

An emission layer EML may be disposed on the first electrode E1. The emission layer EML may include at least one of an organic material and an inorganic material. The emission layer EML may generate colored light.

A second electrode E2 may be disposed on the emission layer EML. The second electrode E2 may include a reflective metal including calcium (Ca), barium (Ba), magnesium (Mg), aluminum (Al), silver (Ag), gold (Au), nickel (Ni) chromium (Cr), lithium (Li), calcium (Ca), or molybdenum (Mo) or a transparent conductive oxide (TCO) such as indium tin oxide (ITO) or indium zinc oxide (IZO).

The first electrode E1, the emission layer EML, and the second electrode E2 may configure a light emitting element. The first electrode E1 may be an anode, which is a hole injection electrode, and the second electrode E2 may be a cathode, which is an electron injection electrode. However, the first electrode E1 may be a cathode and the second electrode E2 may be an anode, according to a driving method of the light emitting display device.

Holes and electrons from the first electrode E1 and the second electrode E2, respectively, may be injected into the emission layer EML and light may be emitted when excitons in which the injected holes and electrons are combined drop from an excited state to a ground state.

A first functional layer FL1 may be disposed between the emission layer EML and the first electrode E1, and a second functional layer FL2 may be disposed between the emission layer EML and the second electrode E2.

The first functional layer FL1 may include at least one of a hole injection layer HIL and a hole transporting layer HTL, and the second functional layer FL2 may include at least one of an electron transporting layer ETL and an electron injection layer EIL.

Each of the first functional layer FL1 and the second functional layer FL2 may entirely cover the substrate 100. Each of the first functional layer FL1 and the second functional layer FL2 may entirely cover the display area of the substrate 100.

An encapsulation layer EL may be disposed on the second functional layer FL2. The encapsulation layer EL may encapsulate or seal the light emitting diode to prevent ambient moisture or oxygen from penetrating. The encapsulation layer EL may include at least one of an inorganic layer and an organic layer. For example, the encapsulation layer EL may include a first inorganic layer, an organic layer, and a second inorganic layer. The first inorganic layer may be disposed on the second functional layer FL2, and may include an inorganic material. The organic layer may be disposed on the first inorganic layer and may include an organic material. The upper surface of the organic layer may be planarized. The second inorganic layer may be disposed on the organic layer and may include an inorganic material. The first inorganic layer and the second inorganic layer may include the same inorganic material.

A touch sensing layer TSL may be disposed on the encapsulation layer EL. The touch sensing layer TSL may detect a touch when an object approaches the touch sensing layer TSL or contacts the touch sensing layer TSL. The touch includes not only a case where an external object such as a user's hand directly contacts the touch sensing layer TSL, but also a case where the external object approaches or hovers in a state of approaching the touch sensing layer TSL.

The touch sensing layer TSL may include a sensing electrode and an insulating film. For example, the touch sensing layer TSL may include a first sensing electrode disposed on the encapsulation layer EL, a first touch insulating film disposed on the first sensing electrode, a second sensing electrode disposed on the first touch insulating film, and a second touch insulating film disposed on the second sensing electrode. The first sensing electrode and the second sensing electrode might not overlap each other. For example, the first sensing electrode and the second sensing electrode may be disposed offset from each other or alternately.

The first sensing electrode and the second sensing electrode may include a transparent conductive oxide (TCO) such as indium tin oxide (ITO) and indium zinc oxide (IZO). The first touch insulating film may include an organic material. The upper surface of the first touch insulating film may have a fine uneven structure and may be planarized. The second touch insulating film may include an inorganic material.

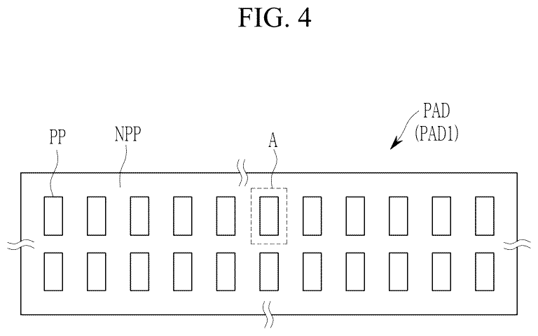

FIG. 4 is a schematic top plan view of a portion of a pad portion of a display device according to an embodiment. FIG. 4 is a schematic top plan view of a portion of the driving pad portion of the display device described with reference to FIG. 1 and FIG. 2. In FIG. 4, for better understanding and ease of description, a diagram of a configuration of the driving integrated circuit is omitted. To the extent that an element is not described in detail with respect to this figure, it may be understood that the element is at least similar to a corresponding element that has been described elsewhere within the present disclosure.

Referring to FIG. 4, the pad portion PAD may include a plurality of pads P. As described above, the pad portion PAD may be disposed in a non-display area, and may include a pad area PP in which the pad P is disposed and a non-pad area NPP surrounding the pad area PP. The pad portion PAD shown in FIG. 4 may be a driving pad portion PAD1.

Each pad P is spaced apart from the others and may have an approximately rectangular planar shape. Additionally, unlike the illustrated embodiment, each pad P may have different planar shapes, such as a parallelogram shape or something substantially similar thereto.

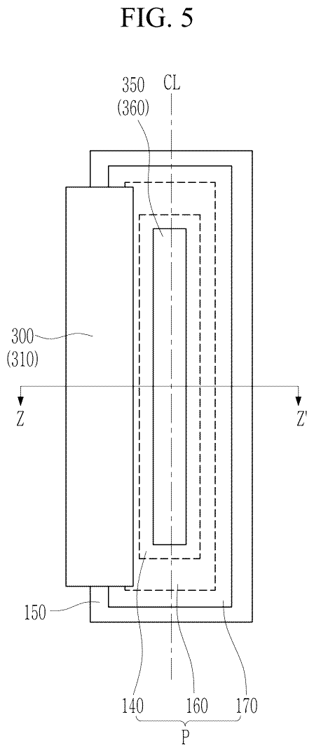

FIG. 5 is a schematic top plan view of a portion of a pad portion of a display device according to an embodiment. FIG. 5 is an enlarged top plan view of area A of FIG. 4.

Referring to FIG. 4 and FIG. 5, a first pattern layer 300 and a second pattern layer 350 may be disposed between a third pad electrode 170 and a conductive layer 250. The first pattern layer 300 and the second pattern layer 350 may partially overlap the pad P. The first pattern layer 300 and the second pattern layer 350 may be spaced apart from each other.

The first pattern layer 300 may overlap a portion of the pad area PP and a portion of the non-pad area NPP. A portion of the first pattern layer 300 may be disposed on the pad area PP in which the pad P is formed, and the remaining portion may be disposed on the non-pad area NPP in which the pad P is not formed. The first pattern layer 300 may be disposed on the third pad electrode 170, an interlayer insulating layer 150, and the substrate 100. The first pattern layer 300 may be disposed in contact with the upper surface of the third pad electrode 170, the upper surface of the interlayer insulating layer 150, and the upper surface of the buffer layer 110 disposed on the substrate 100.

The second pattern layer 350 may overlap a portion of the pad area PP. The second pattern layer 350 may include a center line CL of the pad P. The second pattern layer 350 may be disposed while contacting the upper surface of the third pad electrode 170 while including the center line CL of the pad P.

In one embodiment, the first pattern layer 300 may be disposed on one side with respect to the second pattern layer 350. For example, the first pattern layer 300 may be disposed on either side of the center line CL with respect to the second pattern layer 350. For example, the first pattern layer 300 may be disposed only on either side of the center line CL with the second pattern layer 350 interposed therebetween. When the first pattern layer 300 is formed on both sides of the second pattern layer 350, a driving bump 420 does not contact the first pattern layer 300 due to the first pattern layers 300 disposed on both sides of the second pattern layer 350, and thus the bonding strength may be reduced. The first pattern layer 300 is disposed only on one side of the second pattern layer 350, so that even if the first pattern layer 300 is formed, the driving bumps to be described later may contact the conductive layer formed on the upper surface of the second pattern layer 350. Therefore, the bonding strength between the driving bump and the conductive layer 250 disposed on the pad P may be increased.

The first height h1 of the first pattern layer 300 may be greater than the second height h2 of the second pattern layer 350. The first height h1 refers to the maximum height of the first pattern layer 300 measured in a direction that is perpendicular to the upper surface from the upper surface of the substrate 100. The second height h2 refers to the maximum height of the second pattern layer 350 measured in a direction that is perpendicular to the upper surface from the upper surface of the substrate 100. The first pattern layer 300 and the second pattern layer 350 are formed such that the first height h1 is greater than the second height h2, so that the driving bump 420 may be in contact with the side surface of the first pattern layer 300 and the upper surface of the second pattern layer 350. Accordingly, the contact stability of a driver 400 and the pad portion PAD may be improved.

In one embodiment, in the thickness measured in a direction that is perpendicular to the upper surface from the upper surface of the substrate 100, the maximum thickness of the first pattern layer 300 may be within a range of about 2 μm to about 5 μm, about 3 μm to about 5 μm, or about 4 μm to about 5 μm, inclusive. In the above ranges, the upper surface of the first pattern layer 300 may be formed higher than the upper surface of the third pad electrode 170.

In one embodiment, in the thickness measured in a direction that is perpendicular to the upper surface from the upper surface of the substrate 100, the maximum thickness of the second pattern layer 350 may be within a range of 0.5 μm to 3 μm, 1 μm to 3 μm, or 1.5 μm to 2.5 μm, inclusive. In the above range, the pad P and the driver 400 may be sufficiently spaced apart from each other. Accordingly, the structure of the pad P may be prevented from being distorted by the driver 400, and signal interference by the driver 400 may be prevented.

The first pattern layer 300 may include a single first segment 310. For example, the first pattern layer 300 may be formed of one first segment 310 having a quadrangular shape. FIG. 5 illustrates that the first segment 310 has a rectangular plane, but the shape of the first segment 310 is not necessarily limited thereto. As the first pattern layer 300 is formed of the single first segment 310, a contact area between the first pattern layer 300 and the driving bump 420 may be further increased.

The second pattern layer 350 may include a single second segment. For example, the second pattern layer 350 may be formed of one second segment 360 having a quadrangular shape. FIG. 5 illustrates that the second segment 360 has a rectangular plane, but the shape of the second segment 360 is not necessarily limited thereto. As the second pattern layer 350 is formed of the single second segment 360, a contact area between the second pattern layer 350 and the driving bump 420 may be further increased.

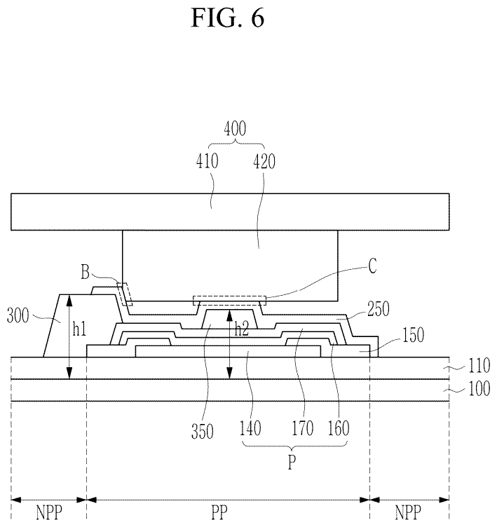

FIG. 6 is a schematic cross-sectional view of a portion of a pad portion of a display device according to an embodiment. FIG. 6 is a schematic cross-sectional view taken along line Z-Z′ of FIG. 5.

Referring to FIG. 4 to FIG. 6, the pad P may include a first pad electrode 140, a second pad electrode 160, and a third pad electrode 170. Hereinafter, to describe the relationship with the structure of the display area DA, reference is made to FIG. 1 and FIG. 2 together.

The first pad electrode 140 may be disposed on the substrate 100. The buffer layer 110 may be disposed on the substrate 100, and the first pad electrode 140 may be disposed on the buffer layer 110. The first pad electrode 140 may include the same material as the gate electrode GE of the display area DA described with reference to FIG. 3. The first pad electrode 140 may be formed by the same process as the gate electrode GE of the display area DA. For example, the first pad electrode 140 may be formed together, forming the gate electrode GE of the display area DA.

The first pad electrode 140 may be formed in a single-layered structure, or may be formed in a multi-layered structure. Even when the first pad electrode 140 is formed in a multi-layered structure, it may be formed together with the gate electrode GE of the display area DA and may include the same material as the gate electrode GE. A gate insulating film may be disposed between the first pad electrode 140 and the buffer layer 110.

The interlayer insulating layer 150 may be disposed on the first pad electrode 140 and the substrate 100, and the second pad electrode 160 may be disposed on the interlayer insulating layer 150. The buffer layer 110 may be disposed on the substrate 100, and the interlayer insulating layer 150 may be disposed on the first pad electrode 140 and the buffer layer 110. The second pad electrode 160 may be disposed on the buffer layer 110. The second pad electrode 160 may be connected to the first pad electrode 140 through a contact hole formed in the interlayer insulating layer 150.

The interlayer insulating layer 150 may include the same material as insulating layers such as the first gate insulating layer GI1, the second gate insulating layer GI2, and the first insulating layer ILD1 disposed in the display area described with reference to FIG. 3. The interlayer insulating layer 150 may be formed by the same process as the insulating layers such as the first gate insulating layer GI1, the second gate insulating layer GI2, and the first insulating layer ILD1.

The second pad electrode 160 may include the same material as the source electrode SE and the drain electrode DE disposed in the display area DA. The second pad electrode 160 may be formed by the same process as the source electrode SE and the drain electrode DE.

The third pad electrode 170 may be formed on the second pad electrode 160. The third pad electrode 170 may include the same material as the source electrode SE and the drain electrode DE disposed in the display area described with reference to FIG. 3. The third pad electrode 170 may be formed by the same process as the source electrode SE and the drain electrode DE. For example, the source electrode SE and the drain electrode DE may be formed in a multi-layered structure in the display area DA, and the second pad electrode 160 may be formed by the same process as the source electrode SE and the drain electrode DE on the lower side of the multi-layered structure. Additionally, the third pad electrode 170 may be formed by the same process as the source electrode SE and the drain electrode DE on the upper side of the multi-layered structure.

The second pad electrode 160 and the third pad electrode 170 may be formed separately from the source electrode SE and the drain electrode DE by a different process.

The conductive layer 250 may be formed on the third pad electrode 170. The conductive layer 250 may include the same material as the sensing electrode of the touch sensing layer TSL disposed in the display area described with reference to FIG. 3. For example, it may include the same material as the first sensing electrode and the second sensing electrode disposed on the touch sensing layer TSL. The conductive layer 250 may be formed by the same process as the sensing electrode of the touch sensing layer TSL. The conductive layer 250 may be formed separately from the touch sensing layer TSL by a different process.

The display device may further include a driver 400 for driving the display device. The driver 400 may include a driving integrated circuit 410 and a driving bump 420. The driving integrated circuit 410 of the driver 400 may have a configuration corresponding to the driving integrated circuit 50 described with reference to FIG. 1. The driving bump 420 may be disposed on one surface of the driving integrated circuit 410 and may face the pad P.

In one embodiment, the driving bump 420 may be in contact with the conductive layer 250 disposed on the first pattern layer 300 and the conductive layer 250 disposed on the second pattern layer 350. Accordingly, the contact area between the driving bump 420 and the conductive layer 250 formed on the pad P may increase. Therefore, the bonding stability of the driver 400 and the pad P through conductive layer 250 may be increased.

For example, the driving bump 420 may be in contact with the conductive layer 250. For example, the driver 400 may be disposed on the pad portion PAD to be in contact with the conductive layer 250. The driver 400 may be disposed on the driving pad portion PAD1. For example, the driving pad portion PAD1 may span the pad area PP and the non-pad area NPP.

Referring to area B of FIG. 6, the driving bump 420 may be in contact with the conductive layer 250 disposed on the side surface of the first pattern layer 300. The side surface of the first pattern layer 300 may have an inclined surface, and the driving bump 420 may be in contact with the conductive layer 250 disposed on the inclined surface. For example, the side surface of the first pattern layer 300 and the corner portion of the driving bump 420 may be in contact with each other. Accordingly, the driving bump 420 may be in line contact with the conductive layer 250 disposed on the first pattern layer 300, and pressure may be concentrated on the corner portion of the driving bump 420. Therefore, when the driving bump 420 is bonded to the conductive layer 250 on the first pattern layer 300, the shape of the driving bump 420 may be changed due to pressure concentration, thereby increasing the contact area, and reducing the interfacial resistance due to bonding.

The driving bump 420 may be in contact with the conductive layer 250 disposed on the side surface of the first pattern layer 300 to have a contact area. The contact area may have an inclined surface. For example, the corner portion of the driving bump 420 in line contact may be deformed by heat and pressure to form an inclined surface having a predetermined area. Accordingly, the contact area between the driving bump 420 and the pad P may be increased, and interfacial resistance due to bonding may be reduced.

Referring to area C of FIG. 6, the driving bump 420 may be in contact with the conductive layer 250 disposed on the upper surface of the second pattern layer 350. For example, the driving bump 420 may be in contact with the conductive layer 250 disposed on the side surface of the first pattern layer 300 and the conductive layer 250 disposed on the upper surface of the second pattern layer 350. Accordingly, the contact area of the driving bump 420 and the conductive layer 250 may be further increased. Therefore, in the bonding of the driver 400 and the pad P through the conductive layer 250, bonding stability may be improved, and interfacial resistance due to bonding may be reduced.

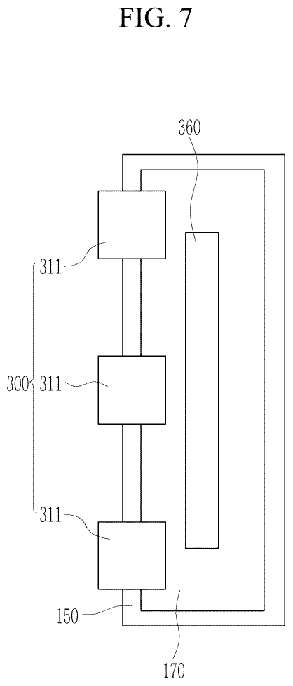

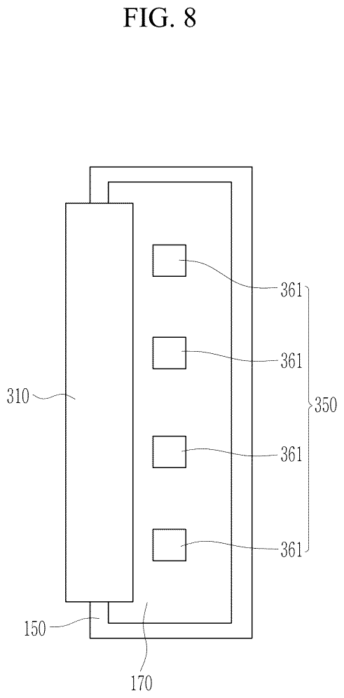

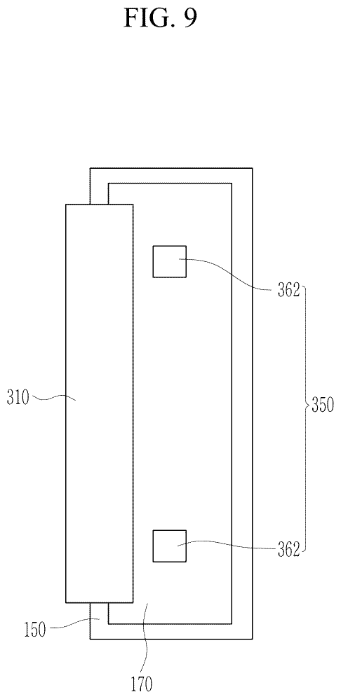

FIG. 7 to FIG. 10 are schematic top plan views of a portion of a pad portion of a display device according to an embodiment. FIG. 7 to FIG. 10 are enlarged top plan views of area A of FIG. 4.

Referring to FIG. 7 to FIG. 10, at least one of the first segments 310 and 311 configuring the first pattern layer 300 and the second segments 360, 361, and 362 configuring the second pattern layer 350 may be formed in plural.

In the embodiment, the first pattern layer 300 may include a plurality of first segments 311. For example, as shown in FIG. 7, the first segment 310 may include a plurality of first segments 311 spaced apart from each other. The number of the plurality of first segments 311 is not necessarily limited to what is shown. For example, the first pattern layer 300 may be configured of two, three, or four first segments 311. The first pattern layer 300 may be configured of five or more first segments 311.

The shape of the first segment 310 is not necessarily limited to what is shown. FIG. 7 illustrates that a plurality of first segments 311 having a square plane shape are formed, but the shape of the plurality of first segments 311 is not necessarily limited thereto. As the first pattern layer 300 is configured of a plurality of first segments 311, pressure concentration between the conductive layer 250 and the driving bump 420 formed on the first pattern layer 300 may increase. Accordingly, the bonding stability between the pad P and the driver 400 by the conductive layer 250 may be further increased.

In the embodiment, the second pattern layer 350 may include a plurality of second segments 361 and 362. For example, as shown in FIG. 8 and FIG. 9, the second segment 360 may include a plurality of second segments 361 and 362 spaced apart from each other. The number of the plurality of second segments 361 and 362 is not necessarily limited to what is shown. For example, the second pattern layer 350 may be configured of two, three, or four second segments 361 and 362. The second pattern layer 350 may be configured of five or more second segments 361 and 362.

The shape of the second segment 360 is not necessarily limited to what is shown. FIG. 8 and FIG. 9 illustrate that a plurality of second segments 361 and 362 having a square planar shape are formed, but the shape of the plurality of second segments 361 and 362 is not necessarily limited thereto. As the second pattern layer 350 is configured of a plurality of second segments 361 and 362, pressure concentration may occur between the conductive layer 250 and the driving bump 420 formed on the second pattern layer 350. Accordingly, the bonding stability between the pad P and the driver 400 by the conductive layer 250 may be further increased.

In the embodiment, the first pattern layer 300 and the second pattern layer 350 may each include a plurality of first segments 310 and second segments 360. For example, as shown in FIG. 10, both the first segment 310 and the second segment 360 may include a plurality of first segments 311 and a plurality of second segments 361 that are spaced apart from each other. The number of the plurality of first segments 311 and the plurality of second segments 361 is not necessarily limited to what is shown.

The first pattern layer 300 and the second pattern layer 350 may include organic insulating materials such as polymers such as polymethyl methacrylate (PMMA) and polystyrene (PS), polymer derivatives having phenolic groups, acrylic polymers such as acrylic polymers, imide polymers such as polyimide, and siloxane polymers. For example, the first segment 310 configuring the first pattern layer 300 and the second segment 360 configuring the second pattern layer 350 may include the above materials. The first pattern layer 300 and the second pattern layer 350 may include the same material or different materials.

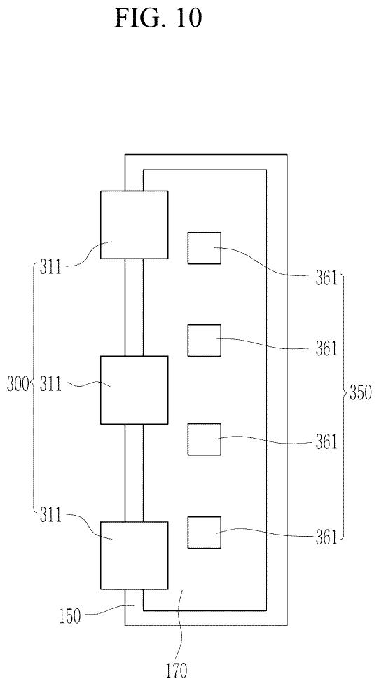

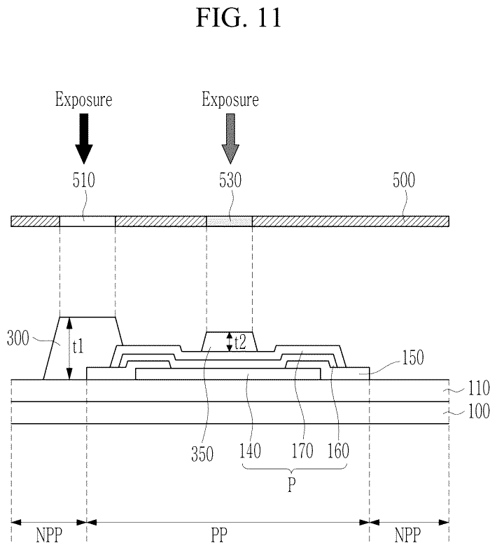

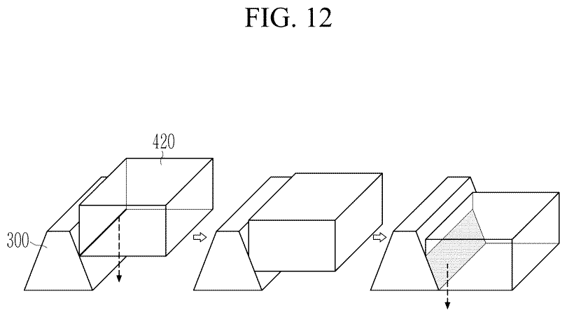

FIG. 11 and FIG. 12 are schematic diagrams of a method of manufacturing a display device according to an embodiment. FIG. 11 is a schematic view for explaining the process of forming a mask pattern using a photomask. FIG. 12 is a schematic view for explaining the process of attaching a driver to a pad. FIG. 12 is a schematic diagram for explaining the process of changing the edge portion of a driving bump from line contact to surface contact during the process of attaching a driver to a pad. For better understanding and ease of description, the illustration of the conductive layer is omitted in FIG. 12. To the extent that an element is not described in detail with respect to this figure, it may be understood that the element is at least similar to a corresponding element that has been described elsewhere within the present disclosure.

Referring to FIG. 11, in a pad portion including a pad area PP that is formed in a non-display area of a display panel and in which a pad P is disposed and a non-pad area NPP that surrounds the pad area, a plurality of pattern layers 300 and 350 may partially overlap the pad P.

In one embodiment, the forming of the pattern layers 300 and 350 may include forming a first pattern layer 300 to overlap a portion of the pad area PP and a portion of the non-pad area NPP, and forming a second pattern layer 350 to overlap a portion of the pad area PP and include a center line of the pad P. For example, the first pattern layer 300 may be formed on the third pad electrode 170, the interlayer insulating layer 150, and the substrate 100, while being in contact with the upper surface of the third pad electrode 170, the upper surface of the interlayer insulating layer 150, and the upper surface of the buffer layer 110 disposed on the substrate 100. For example, the second pattern layer 350 may be formed on the third pad electrode 170 to include the center line of the pad P while contacting the upper surface of the third pad electrode 170.

In one embodiment, the pattern layers 300 and 350 may be formed using a photomask 500 including a first mask pattern 510 and a second mask pattern 530 having lower light transmittance than the first mask pattern 510. The first pattern layer 300 corresponding to the first mask pattern 510 and the second pattern layer 350 corresponding to the second mask pattern 530 may be formed by using the photomask 500.

The photomask 500 may be a halftone mask. The halftone mask may include a light transmitting portion formed on a transparent substrate, a light blocking portion blocking light, and a semi-transmitting portion that adjusts transmittance to transmit a portion of light. For example, the first mask pattern 510 may be the light transmitting portion, and the second mask pattern 530 may be the semi-transmitting portion. For example, the first mask pattern 510 and the second mask pattern 530 may be semi-transmitting portions having different light transmittances.

The light transmittance of the first mask pattern 510 may be 95% or more, 98% or more, or 100%. For example, the first pattern layer 300 may be formed using the first mask pattern 510 having the light transmittance within the above ranges. For example, as shown in FIG. 11, the first pattern layer 300 may be formed through an exposure process using the first mask pattern 510.

The light transmittance of the second mask pattern 560 may be within a range of about 40% to about 60%, about 45% to about 60%, or about 45% to about 55%, inclusive. For example, the second pattern layer 350 may be formed using the second mask pattern 560 having the light transmittance within the above ranges. For example, as shown in FIG. 11, the second pattern layer 350 may be formed through an exposure process using the second mask pattern 530. Accordingly, the maximum thickness of the first pattern layer 300 may be greater than the maximum thickness of the second pattern layer 350.

In the embodiment, the pattern layers 300 and 350 may be formed so that the first thickness t1 of the first pattern layer 300 is greater than the second thickness t2 of the second pattern layer 350. The first thickness t1 refers to the maximum thickness measured in a direction that is perpendicular to the lower surface of the first pattern layer 300. The second thickness t2 refers to the maximum thickness measured in the first direction DR1 perpendicular to the lower surface of the second pattern layer 350.

The first pattern layer 300 may have the first thickness t1, which is the maximum thickness of the first pattern layer 300 within a range of about 2 μm to about 5 μm, about 3 μm to about 5 μm, or about 4 μm to about 5 μm, inclusive. Within the above range, the upper surface of the first pattern layer 300 may be higher than the third pad electrode 170.

The second pattern layer 350 may have the second thickness t2, which is the maximum thickness of the second pattern layer 350 within a range of about 0.5 μm to about 3 μm, about 1 μm to about 3 μm, or about 1.5 μm to about 2.5 μm, inclusive. In the above ranges, the pad P and the driver 400 may be sufficiently spaced apart from each other. Accordingly, the structure of the pad P may be prevented from being distorted by the driver 400, and signal interference by the driver 400 may be prevented.

In one embodiment, the conductive layer 250 may be formed on the plurality of pattern layers 300 and 350. The conductive layer 250 may be formed as an intermediate layer for attaching the pad P and the driver. The conductive layer 250 may be formed together with the touch sensing layer TSL of the display area as described above with reference to FIG. 1 and FIG. 2.

In one embodiment, the driver including the driving bump and the driving integrated circuit may be disposed on the plurality of pattern layers 300 and 350 and may overlap the pad P. For example, the driver may be disposed so that the driving bump of the driver overlaps the side surface of the first pattern layer 300 and the upper surface of the second pattern layer 350.

Referring to FIG. 12, the driving bump 420 may be bonded to the conductive layer to attach the driver to the pad P.

The driver including the driving bump 420 may be moved so that the corner portion of the driving bump 420 and the conductive layer formed on the side surface of the first pattern layer 300 are in contact with one another. Accordingly, the driving bump 420 and the conductive layer formed on the side surface of the first pattern layer may be in line contact with one another. Therefore, pressure may be concentrated between the driving bump 420 and the conductive layer formed on the side surface of the first pattern layer 300.

Pressure may be applied to the driver including the driving bump 420 in line contact with the conductive layer formed on the side surface of the first pattern layer 300 to move the driver including the driving bump 420 in the lower surface direction of the first pattern layer 300. Accordingly, as the pressure between the driving bump 420 and the conductive layer formed on the side surface of the first pattern layer 300 increases to generate heat, the driver moves downward (for example, in the direction of the pad), and the shape of the corner portion of the driving bump 420 may be deformed. For example, the corner portion of the driving bump 420 may have the same inclined surface as the inclined surface of the conductive layer formed on the side surface of the first pattern layer 300.

As the shape of the corner portion of the driving bump 420 is deformed, the driving bump 420 and the conductive layer formed on the side surfaces of the first pattern layer 300 may be bonded. Additionally, the driving bump 420 may contact the conductive layer formed on the upper surface of the second pattern layer 350 to be bonded to it.

Accordingly, the driver and the pad P may be attached while increasing the contact area between the driving bump 420 and the conductive layer. Accordingly, the contact area between the driver and the pad P may increase, and interfacial resistance due to bonding may decrease.

A display device including a non-display area including a driver attached to a pad manufactured by the above-described method may be manufactured.

A display device, according to an embodiment, may be applied to various electronic devices. An electronic device, according to an embodiment, may include the display device, and may further include modules or devices having additional functions other than the display device.

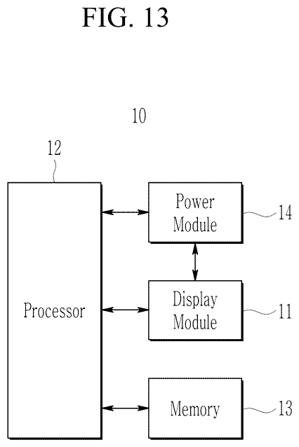

FIG. 13 is a block diagram of an electronic device according to an embodiment. Referring to FIG. 13, the electronic device 10, according to an embodiment, may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for operations of the processor 12 or the display module 11. When the processor 12 executes an application stored in the memory 13, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 11 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 11 that are not part of the display device.

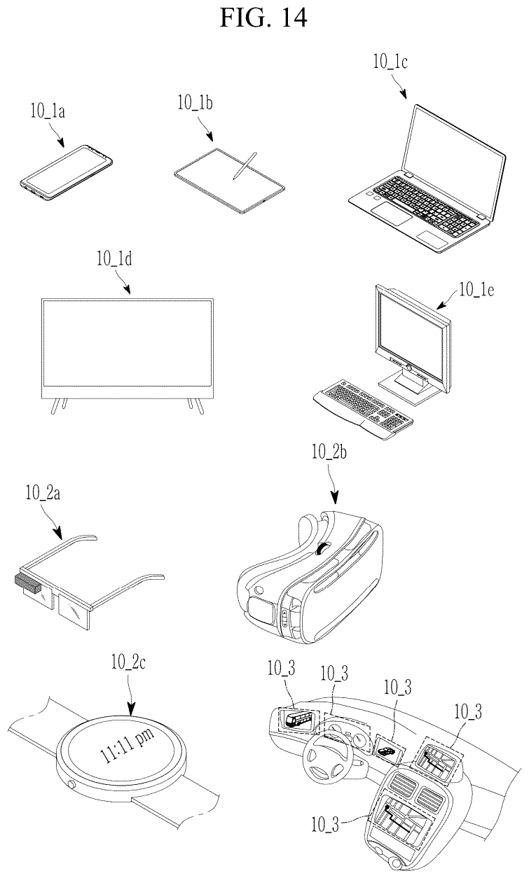

FIG. 14 shows schematic diagrams of electronic devices according to various embodiments.

Referring to FIG. 14, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

While the embodiment of the present disclosure has been described in connection with what are presently considered to be practical embodiments, it is to be understood that the disclosure is not necessarily limited to the disclosed embodiments, but, on the contrary, is intended to cover various modifications and equivalent arrangements included within the spirit and scope of the present disclosure.

What is claimed is:

1. A display device, comprising:
a substrate including a display area and a non-display area that is proximate to the display area;
a pad portion disposed in the non-display area and including a pad area, in which a pad is disposed, and a non-pad area surrounding the pad area; and
a first pattern layer and a second pattern layer each partially overlapping the pad and spaced apart from each other,
wherein the first pattern layer is overlaps a portion of the pad area and a portion of the non-pad area,
wherein the second pattern layer overlaps a portion of the pad area and includes a center line of the pad, and
wherein, in a maximum height measured in a first direction that is perpendicular to an upper surface of the substrate from the upper surface thereof, a first height of the first pattern layer is greater than a second height of the second pattern layer.

2. The display device of claim 1, wherein the first pattern layer includes a single first segment.

3. The display device of claim 1, wherein the first pattern layer includes a plurality of first segments that are spaced apart from each other.

4. The display device of claim 1, wherein the second pattern layer includes a single second segment.

5. The display device of claim 1, wherein the second pattern layer includes a plurality of second segments that are spaced apart from each other.

6. The display device of claim 1, wherein a maximum thickness of the second pattern layer, measured in the first direction, is within a range of 0.5 μm to 3 μm, inclusive.

7. The display device of claim 1, wherein the first pattern layer is disposed on one side of the second pattern layer.

8. The display device of claim 1, wherein:
the display device further includes a driver that drives the display device, and
the driver includes a driving integrated circuit and a driving bump connecting the driving integrated circuit to the substrate.

9. The display device of claim 8, wherein:
the display device further includes a conductive layer formed on the first pattern layer and the second pattern layer, and
the driving bump is in contact with the conductive layer.

10. The display device of claim 9, wherein the driving bump is in contact with the conductive layer disposed on the first pattern layer and the conductive layer disposed on the second pattern layer.

11. The display device of claim 10, wherein the driving bump is in contact with the conductive layer disposed on a side surface of the first pattern layer.

12. The display device of claim 11, wherein:
the side surface of the first pattern layer has an inclined surface, and the driving bump is in contact with the conductive layer disposed on the inclined surface.

13. The display device of claim 11, wherein an area in which the driving bump of the driver and the conductive layer disposed on the side surface of the first pattern layer are in contact with each other has an inclined surface.

14. The display device of claim 10, wherein the driving bump is in contact with the conductive layer disposed on an upper surface of the second pattern layer.

15. An electronic device, comprising:
a display device including:
a substrate including a display area and a non-display area that is proximate to the display area;
a pad portion disposed in the non-display area and including a pad area in which a pad is disposed and a non-pad area surrounding the pad area; and
a first pattern layer and a second pattern layer partially overlapping the pad and spaced apart from each other,
wherein the first pattern layer overlaps a portion of the pad area and a portion of the non-pad area,
wherein the second pattern layer overlaps a portion of the pad area and includes a center line of the pad, and
wherein in a maximum height measured in a first direction that is perpendicular to an upper surface of the substrate from the upper surface thereof, a first height of the first pattern layer is greater than a second height of the second pattern layer.

16. A method of manufacturing a display device, comprising:
forming, in a pad portion, a plurality of pattern layers partially overlapping a pad, the pad portion disposed in a non-display area and including a pad area in which the pad is disposed and a non-pad area surrounding the pad area;
forming a conductive layer on the plurality of pattern layers;
disposing a driver including a driving bump and a driving integrated circuit so as to overlap the pad on the plurality of pattern layers; and
bonding the driving bump to the conductive layer to attach the driver to the pad,
wherein the forming of the pattern layers includes preparing a photomask including a first mask pattern and a second mask pattern having a lower light transmittance than the first mask pattern, and
forming a first pattern layer corresponding to the first mask pattern and a second pattern layer corresponding to the second mask pattern using the photomask.

17. The method of manufacturing the display device of claim 16, wherein the forming of the pattern layers includes:
forming the first pattern layer overlapping a portion of the pad area and a portion of the non-pad area, and
forming the second pattern layer overlapping a portion of the pad area and include a center line of the pad.

18. The method of manufacturing the display device of claim 16, wherein the forming of the pattern layers includes forming the first pattern layer using the first mask pattern having a light transmittance of 95% or more.

19. The method of manufacturing the display device of claim 16, wherein the forming of the pattern layers includes forming the second pattern layer using the second mask pattern having a light transmittance within a range of 40% to 60%, inclusive.

20. The method of manufacturing the display device of claim 16, wherein the forming of the pattern layers includes forming a maximum thickness of the first pattern layer to be greater than that of the second pattern layer, thickness measured in a first direction that is perpendicular to a lower surface of the pattern layers.
